(19) United States
(12) Patent Application Publication
(10) Pub. No.: US 2026/0128747 A1
(43) Pub. Date: May 7, 2026

(54) SYSTEMS AND METHODS FOR CONVERSION OF ANALOG AND DIGITAL SIGNALS

(71) Applicant: L3Harris Technologies, Inc., Melbourne, FL (US)

(72) Inventor: Aaron T. Sherman, Greenville, TX (US)

(21) Appl. No.: 18/939,688

(22) Filed: Nov. 7, 2024

(51) Int. Cl. H03M 1/02; H03M 1/12

(52) U.S. Cl. CPC H03M 1/02; H03M 1/124

(57) ABSTRACT

Systems and methods for operating a signal converter. The methods comprise; establishing a first interface between the signal converter and an analog device of a first network, and a second interface between the signal converter and an edge node of a different second network; supplying power to a first circuit portion of the signal converter from the analog device, and power to a second circuit portion of the signal converter from the edge node; receiving, by the first circuit portion, a first analog signal from the analog device; converting, by the first circuit portion, the first analog signal to a first electrical signal; formatting, by the second circuit portion, the first electrical signal for communication over the second network; and communicating, from the second circuit portion, the formatted first electrical signal to the edge node.

### BACKGROUND

Communication systems that are moving into the digital age still have significant dependencies on legacy signals and circuits. New digital technology has sunset support for many legacy signals and protocols (e.g., analog audio, discrete input/output (I/O), integrated services digital network (ISDN), public switched telephone network (PSTN), serial) and has replaced them with internet protocol (IP) standards (e.g., voice over IP (VoIP), session (SIP), transmission (TCP), and/or user datagram protocol (UDP)). Support for legacy circuits traditionally requires a piece of conversion equipment that is often a standalone line-replaceable unit (LRU) instead of an integrated solution. This additional equipment adds size, weight and power requirements to the system and can often seem unnecessary when designing a new integrated solution. Additionally, the added conversation equipment is rarely a modern piece of technology and therefore not maintained at the same currency of modern digital technology, leading to obsolescence and limited product support scenarios.

### SUMMARY

This document concerns implementing systems and methods for operating a signal converter. The method comprises: establishing a first interface between the signal converter and an analog device of a first network, and a second interface between the signal converter and an edge node of a different second network; supplying power to a first circuit portion of the signal converter from the analog device, and power to a second circuit portion of the signal converter from the edge node; receiving, by the first circuit portion, a first analog signal from the analog device; converting, by the first circuit portion, the first analog signal to a first electrical signal; formatting, by the second circuit portion, the first electrical signal for communication over the second network; and communicating, from the second circuit portion, the formatted first electrical signal to the edge node.

This document also concerns a signal converter. The signal converter comprises: a first interface configured to be connected between the signal converter and an analog device of a first network; a second interface configured to be connected between the signal converter and an edge node of a different second network; a first circuit portion connected between the first and second interfaces, and configured to receive power from the analog device via the first interface, receive a first analog signal from the analog device, and convert the first analog signal to a first electrical signal; and a second circuit portion connected between the first circuit portion and the second interface, and configured to receive power from the edge node via the second interface, format the first electrical signal for communication over the second network, and communicate the formatted first electrical signal to the edge node.

### BRIEF DESCRIPTION OF THE DRAWINGS

This disclosure is facilitated by reference to the following drawing figures, in which like numerals represent like items throughout the figures.

FIG. 1 provides an illustration of a system implementing the present solution.

FIG. 2 provides an illustration of a small form factor pluggable signal converter being coupled to a network edge device.

FIGS. 3A-3B (collectively referred to as “FIG. 3”) provide perspective views of a signal converter.

FIG. 4 provides a top view of the signal converter shown in FIG. 3.

FIG. 5 provides a side view of the signal converter shown in FIG. 3.

FIG. 6 provides a perspective view of the signal converter shown in FIG. 3 with the housing shown in a semi-transparent form.

FIGS. 7A-7B (collectively referred to as “FIG. 7”) each provides a block diagram for an internal circuit of a signal converter.

FIG. 8 provides a block diagram for an internal circuit of a signal converter.

FIG. 9 provides an illustration that is useful for understanding a circuit board implementation of an internal circuit of a signal converter.

FIG. 10 provides an illustration that is useful for understanding operations of the system shown in FIG. 1.

FIGS. 11A-11B (collectively referred to as “FIG. 11”) provides a flow diagram of an illustrative method for operating a signal converter.

### DETAILED DESCRIPTION

Analog to digital (A/D) conversion exists industry wide and is embedded in technology all around us. The problem with integrating legacy analog circuits into new technology, especially in a military context, is there is always the need for an intermediate piece of equipment to convert the signal into an appropriate digital message. This added equipment is often a single point solution and consumes valuable size, weight and power from the operational environment. Meaning that to convert one analog input signal, a new standalone LRU needs to be mounted, powered and wired and often clutters the design and implementation of the entire system.

The present solution allows analog-conversion-at-the-edge, meaning that analog signals can be brought directly into the IP network architecture and converted to digital as they enter the digital framework without standalone equipment consuming valuable resources from the operational environment. The present solution comprises a small form factor pluggable (SFP) device that bridges analog circuits into the IP network directly as the analog signals enter the digital framework.

The SFP device may be configured to accept analog signal inputs from their native environments, convert the analog signal inputs to digital signals, encode the digital signals into messages, and transmit the messages to network IP endpoints. The SFP device is configured to be compatible with industry standard interfaces to ensure interoperability with multitudes of third-party network equipment and existing IT infrastructure. In this regard, the SFP device may be configured to convert, for example, analog audio and push-to-talk (PTT) signals to digital signals (e.g., signals that can be transmitted over IP to a remote voice network), E1/T1 ISDN signals to VoIP, serial RS232 signals to IP, and/or global positioning system (GPS) sourced time to IP NTP. The SFP device may implement plug-n-play technology that provides immediate expansion of legacy circuits across digital architecture without requiring any physical upgrade to existing network infrastructure. The plug-n-play architecture eliminates the needs for additional conversion boxes, and provides for a relatively easy installation anywhere in the network architecture. The SFP devices may also be used to extend analog or digital signals across an IP network. Not all signals need to stay in the IP realm, therefore the SFP device can convert signals at one end of the network and convert them back at the other end of the network. This feature of the present solution can provide a digital extension cord for legacy systems.

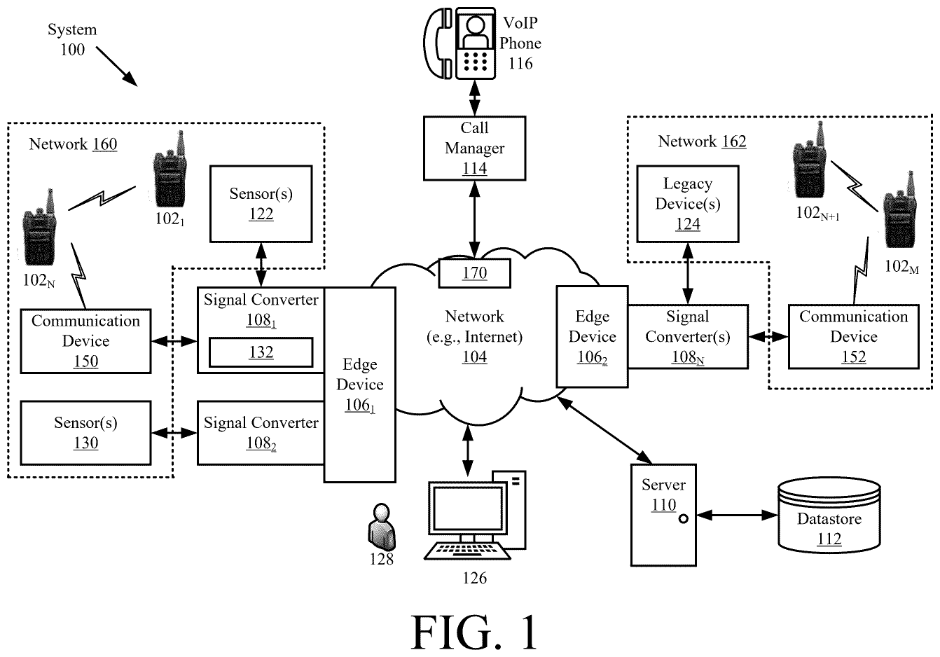

FIG. 1 provides an illustration of system 100 implementing the present solution. System 100 comprises analog networks 160, 162 communicatively connected to each other via a digital network 104. Analog networks 160, 162 can include, but are not limited to, ad hoc radio networks. Digital network 104 can include, but is not limited to, local area networks (LANs) and wide area networks (WANs) including the Internet. In order to facilitate such communications, system 100 comprises signal converter(s) 108₁, 108₂, . . . , 108_{N}. N is an integer equal to or greater than one. Each signal converter 108₁, 108₂, . . . , 108_{N} is configured to receive an analog signal from a first device, convert the analog signal to an electrical or digital signal, and communicate the electrical or digital signal over a network 104 (e.g., the Internet). Each signal converter 108₁, 108₂, . . . , 108_{N} is also configured to receive an electrical or digital signal communicated over the network 104 from a second device, convert the electrical or digital signal to an analog signal, and communicate the analog signal to the first device.

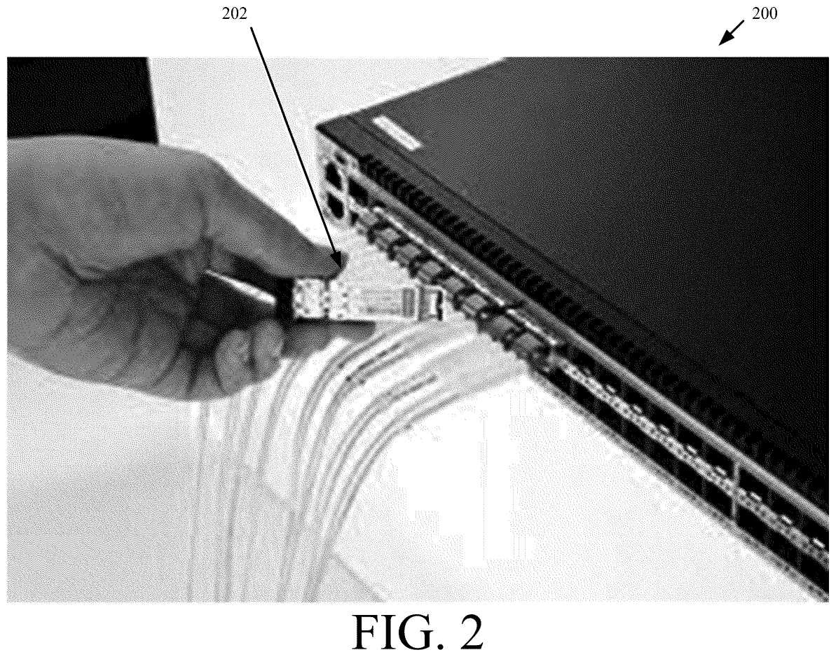

Each signal converter 108₁, 108₂, . . . , 108_{N} is connected to an edge device 106₁, 106₂ of the network 104. Any known or to be known network edge device can be used here. For example, each edge device 106₁, 106₂ may comprise a network box into which the signal converter 108₁, 108₂, . . . , 108_{N} plugs. The network box can include, but is not limited to, a network router or a network switch. In this case, each signal converter 108₁, 108₂, . . . , 108_{N} may be in the form of a small form-factor pluggable (SFP) device. An illustration showing the SFP converter device 202 being plugged into a network edge device 200 is shown in FIG. 2. One or more of the signal converters 108₁, 108₂, . . . , 108_{N} can be the same as or similar to the SFP converter device 202. The present solution is not limited in this regard.

Each signal converter 108₁, 108₂, . . . , 108_{N} is also connected to one or more analog end nodes or devices. For example, signal converter 108₁ is connected to communication device 150 and sensors 122. Signal converter 108₂ is connected to sensor(s) 130. Signal converter 108_{N} is connected to communication device 152 and/or legacy device(s) 124. Communication device(s) 150, 152, sensor(s) 122, 130 and/or legacy device(s) 124 may be located in building(s), ground vehicle(s), aerial vehicle(s), and/or aquatic vehicle(s). Communication devices 150, 152 can include, but are not limited to, radios. Each communication device 150, 152 may be part of an ad-hoc communications network in which it can communicate with portable radios 102₁, . . . , 102_{N}, . . . , 102_{N+1}, . . . , 102_{M}. 122 sensor(s) 122, 130 can include, but are not limited to, radars, object detection sensor(s), proximity sensor(s), heat sensor(s), and/or environmental sensor(s). The legacy device(s) 124 can include, but are not limited to, radio(s) and/or satellite communication device(s).

Signal converter 108₁ is configured to receive an analog signal from communication device 150, convert the analog signal to an electrical or digital signal, and communicate the electrical or digital signal over network 104 to another device such as a VoIP phone 116 (via a call manager 114), a computing device 126, a server 110, a legacy device 124 and/or a communication device 152. Signal converter 108₁ is also configured to receive electrical or digital signal(s) from device(s) 110, 116, 124, 126 and/or 152 via network 104, convert the electrical or digital signal(s) to analog signal(s), and pass the analog signal(s) to communication device 150.

Signal converter 108₂ is configured to receive an analog signal from sensor(s) 122, convert the analog signal to an electrical or digital signal, and communicate the electrical or digital signal over network 104 to another device such as a VoIP phone 116 (via a call manager 114), a computing device 126, a server 110, a legacy device 124 and/or a communication device 152. Signal converter 108₂ is also configured to receive electrical or digital signal(s) from device(s) 110, 116, 124, 126 and/or 152 via network 104, convert the electrical or digital signal(s) to analog signal(s), and pass the analog signal(s) to sensor(s) 122.

Signal converter 108_{N} is configured to receive an analog signal from communication device 152, convert the analog signal to an electrical or digital signal, and communicate the electrical or digital signal over network 104 to another device such as a VoIP phone 116 (via a call manager 114), a computing device 126, a server 110, a legacy device 124 and/or a communication device 150. Signal converter 108_{N} is also configured to receive electrical or digital signal(s) from device(s) 110, 116, 124, 126 and/or 150 via network 104, convert the electrical or digital signal(s) to analog signal(s), and pass the analog signal(s) to communication device 152.

It should be noted that the analog signals communicated to/from a first end node (e.g., communication device 150 or sensor 122) may be different than the analog signals communicated to/from a second end node (e.g., communication device 152 or legacy device 124). For example, different communication protocols and/or modulation techniques are used by the first and second end nodes. Accordingly, a first signal converter (e.g., signal converter 108₁) may be configured to employ a first signal conversion algorithm while a second signal converter (e.g., signal converter 108₂) may be configured to employ a different second signal conversion algorithm. In this way, the first and second signal converters may be configured to facilitate communications between two different analog systems via digital network 104.

Computing device 126 may be used by an operator 128 to selectively connect signals from an edge device 106₁, 106₂ to an end node 122, 124, 130, 150, 152 so that certain operations or functions are performed at the end node. Each signal converter 108₁, . . . , 108_{N} may be configured to facilitate communications between two end nodes via network 104, where at least one of the two end nodes is an analog device.

Additionally or alternatively, operator 128 can facilitate the selective interconnection of a plurality different ends nodes in accordance with a given application. For example, a switch 132 may be provided with the signal converter(s) 108₁ that may be remotely controlled by the operator 128 via computing device 126. Switch 132 may be controlled to transition to a first state in which it forms a connection between communication device 150 and edge device 106₁ at a first time, and controlled to transition to a second state in which it forms a connection between sensor(s) 122 and edge device 106₁ at a second time. In this case, the conversion algorithm employed by the signal converter 108₁ would be changed at the first time and the second time since one or more characteristics of the analog signals communicated to/from the communication device 150 are different from characteristic(s) of the analog signals communicated to/from the sensor(s) 122.

Additionally or alternatively, operator 128 can facilitate the selective interconnection of an edge device 106₁ to end node(s) 130, 150. For example, during a first period of time, the operator 128 performs user-software interactions with computing device 126 to control the system 100 such that signal converter 108₁ is enabled while signal converter 108₂ is disabled. During a second period of time, the operator 128 performs user-software interactions with computing device 126 to control system 100 such that signal converter 108₂ is enable and signal converter 108₁ is disabled.

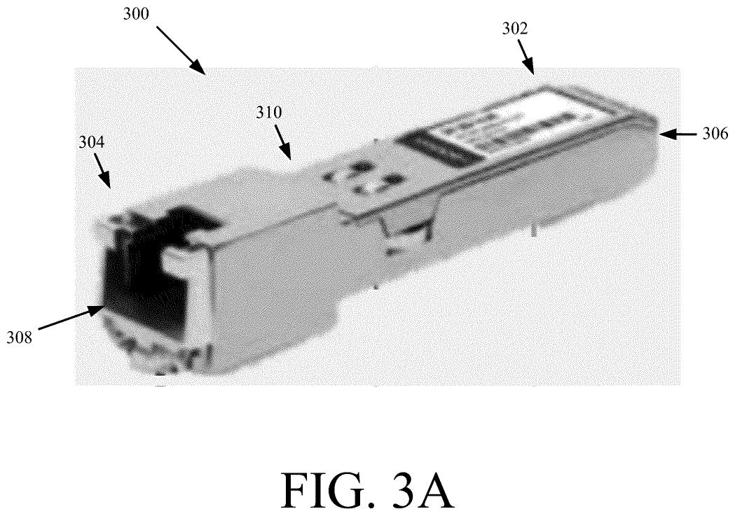

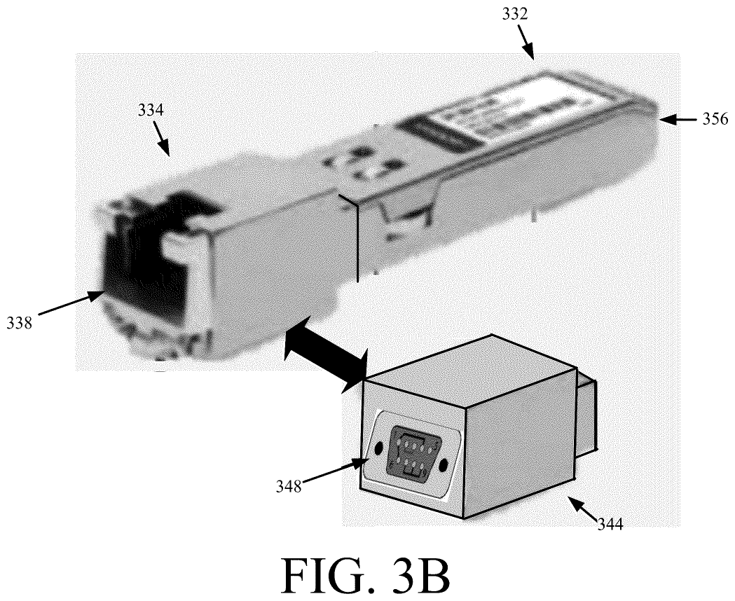

FIG. 3A shows an illustrative architecture for an SFP signal converter 300. Signal converters 108₁, . . . , 108_{N} of FIG. 1 may be the same as or similar to SFP signal converter 300. Thus, the discussion of SFP signal converter 300 is sufficient for understanding signal converters 108₁, . . . , 108_{N} of FIG. 1.

Signal converter 300 comprises a first end 302 with a network connector 306, and an opposing second end 304 with a different type of connector 308. Network connector 306 is configured to interface the signal converter 300 with an edge device of a digital network. Any known or to be known network connector can be used. Connector 308 is configured to connect the signal converter 300 to a node of an analog network. As such, connector 308 can include, but is not limited to, a connector configured to establish an Ethernet, fiber and/or land connection. For example, connector 308 may be an RJ45 connector. The present solution is not limited in this regard. The types of signals that may be communicated to and from connector 308 include, but are not limited to, radio over IP (RoIP) signals, ear and mouth (E&M) audio signals, discrete I/O signals, discrete relay signals, serial data bus signals (e.g., RS232 signals), two-wire data bus signals (e.g., ARINC signal), control bus signals (e.g.,, and/or military standard 1553 signals), aircraft data signals, wideband cipher text signals, public switched telephone network signals (e.g., PSTN telephony), and/or others.

Connectors 306, 308 are connected to a housing 310 in which a circuit is disposed. The circuit will be discussed below. Still, it should be noted here that the circuit is generally configured to convert the analog signals received at connector 308 to a digital signal to be provided to connector 306, and vice versa. The digital signal can include, but is not limited to, IP signals, transmission control protocol (TCP) signals, user datagram protocol (UDP) signals, real-time transport control protocol (RTCP) signals, address resolution protocol (ARP) signals, network time protocol (NTP) signals, hypertext transfer protocol (HTTP) signals HTTP secure (HTTPs) signals, secure shell (SSH) signals, virtual local area network (LAN) signals, real-time transport protocol (RTP) signals, secure RTP (SRTP) signals, and/or transport layer security (TLS) signals.

Signal converter 300 may be an interchangeable component. For example, signal converter 300 may be configured to convert a certain type of analog signal (e.g., analog audio waves), while another signal converter is configured to convert a different type of analog signal (e.g., discrete I/O signals communicated via a data bus, or command and control signals that are analog in nature). The two signal converters may then be interchanged with each other to (re)configure a system in accordance with a particular application. For example, a first signal converter (e.g., signal converter 108₁ of FIG. 1) is plugged into an edge device (e.g., edge device 106₁ of FIG. 2) during a first time period and unplugged from the edge device during a subsequent second time period. A second signal converter (e.g., converter 108₂ of FIG. 1) is plugged into the edge device during the subsequent second time period. The present solution is not limited to the particulars of this example.

Additionally or alternatively, signal converter 300 may be configured to convert two or more different types of analog signals into digital signals. For example, the internal circuit of the converter 300 may be configured to process received analog signals to detect characteristics thereof (e.g., amplitude, phase, frequency, modulation technique, duty cycle, encryption technique, etc.), select a signal conversion algorithm from a plurality of signal conversion algorithms based on the detected signal characteristics, and cause a processor to use the selected signal conversion algorithm to convert the received analog signal to an electrical or digital signal. The signal conversion algorithm may be selected on-the-fly and/or responsive to reception of an analog signal and/or an electrical signal.

Additionally or alternatively, signal converter 300 may comprise two parts 332, 334 that can be selectively coupled to and decoupled from each other as shown in FIG. 3B. First part 332 is configured to connect to a network edge device (e.g., network edge device 106₁ and/or 106₂ of FIG. 1), while a second part 334 is configured to connect to an analog device (e.g., communication device 150, 152 of FIG. 1, sensor(s) 122 of FIG. 1, and/or legacy device(s) 124 of FIG. 1). In this regard, first part 332 comprises the network connector 356, while the second part 334 comprises a different type of connector 358 (e.g., an Ethernet connector). Any known or to be known network connector can be used. The second part 334 may be interchanged with another second part 344 which has yet another different type of connector (e.g., an RS232 connector). In this way, the signal converter 300 may be (re)configured to process analog signals of different types at different times in accordance with respective applications. A processor may be disposed in the first part 332 that is configured to detect which part 334 or 344 is connected to part 332, and select a signal conversion algorithm from a plurality of signal conversion algorithms based on the detected part 334 or 344. The processor may then use the selected signal conversion algorithm to convert analog signals to electrical or digital signals, and vice versa.

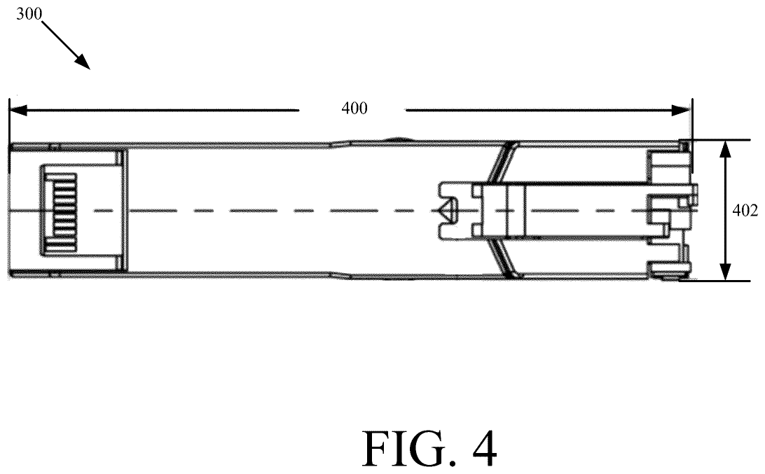

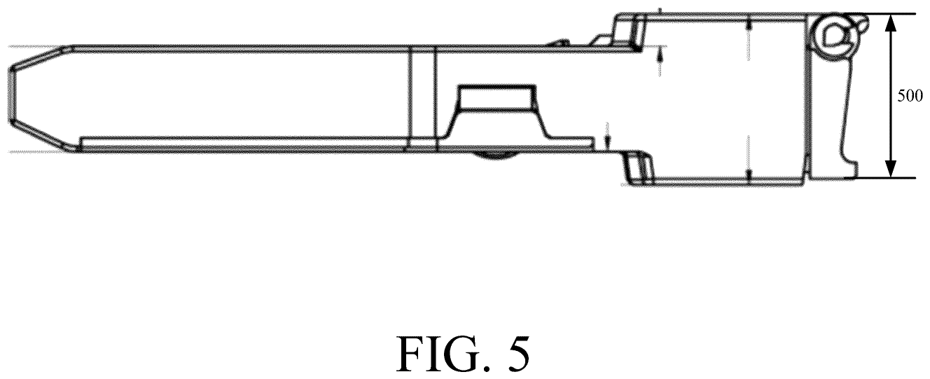

The signal converter 300 may be designed to be relatively small. A top view of the signal converter 300 is provided in FIG. 4. A sideview of the signal converter 300 is provided in FIG. 5. The signal converter 300 has a length 400, a width 402 and a height 500. For example, the length 400 may be between two and four inches. Width 402 may be between half an inch and one inch. Height 500 may be between half an inch and one inch. The present solution is not limited to the particulars of this example. The signal converter can have other dimensions selected in accordance with a given application.

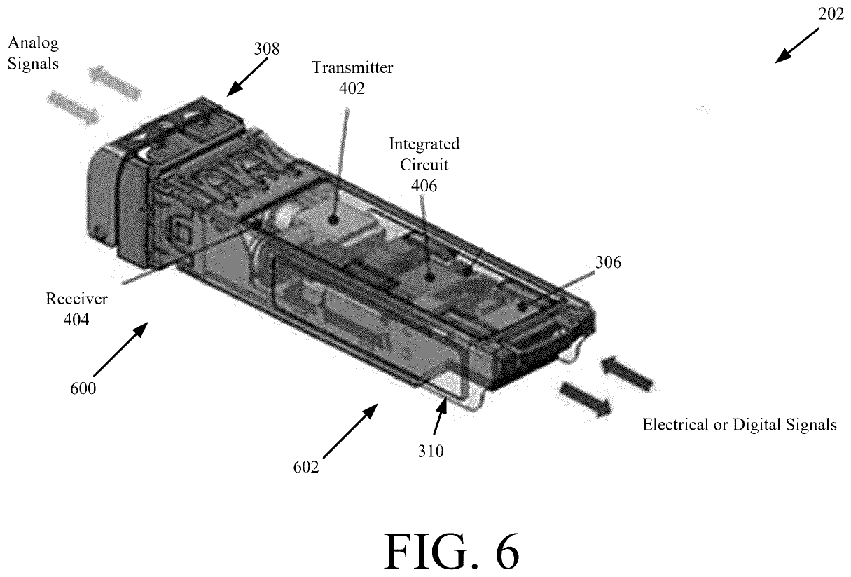

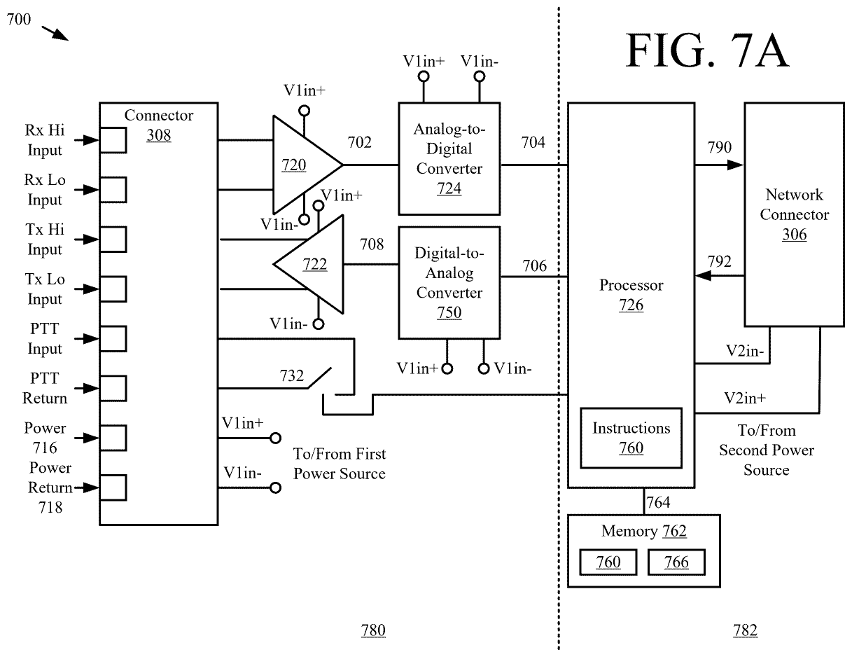

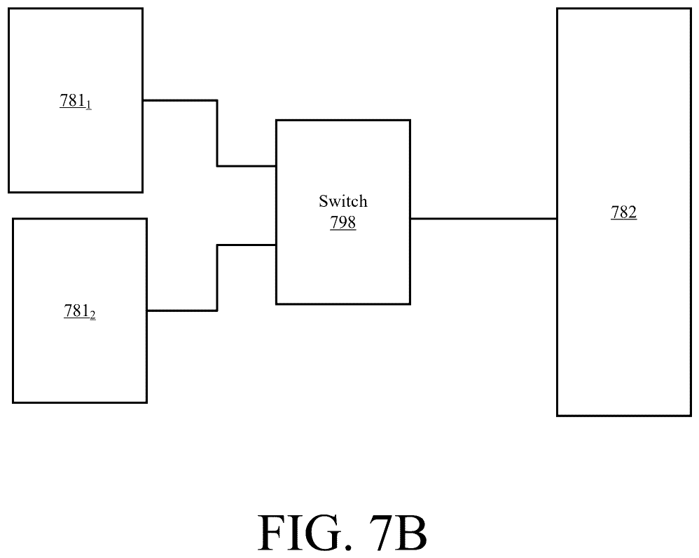

FIG. 6 shows the signal converter 300 with its housing 310 in a partially transparent format so that the internal circuit is visible. Signal converter 300 can include more or less components than that shown in FIG. 7A in accordance with a given application. However, the components shown are sufficient to disclose an illustrative hardware architecture implementing the present solution.

A transceiver 402, 404 is disposed in housing 310 at a distal end 600 of the signal converter 300 to reside adjacent to connector 308. An integrated circuit 406 is disposed in housing 310 at a proximal end 602 of the signal converter 300 to reside adjacent to network connector 306. A more detailed circuit diagram for the signal converter 300 is provided in FIG. 7.

As shown in FIG. 7A, the internal circuit 700 of signal converter 300 comprises a first circuit portion 780 and a second circuit portion 782. Circuit portion 780 is supplied power from a node (e.g., device 122, 124, 130, 150 or 152 of FIG. 1) of a first network (e.g., analog network 160 or 162 of FIG. 1) via power pins 716, 718 of connector 308, while circuit portion 782 is supplied power from an edge device (e.g., edge device 106₁ or 106₂ of FIG. 1) of a second network (e.g., network 104 of FIG. 1) via network connector 308. For example, circuit portion 780 is supplied V1in (e.g., 28 VDC) from the node of the first network, and circuit portion 782 is supplied V2in (e.g., 3.3 VDC) from the edge node. The present solution is not limited to the particulars of this example.

Circuit portion 780 comprises signal conditioners 720, 722 (e.g., audio amplifiers, signal power adjusters, etc.) connected between connector 308 and signal converters 724, 750. Signal conditioner 720 is configured to condition received analog signals for processing by the analog-to-digital (A/D) converter 724. A/D converter 724 is configured to convert analog signals 702 to digital signals 704. The digital signals 704 are provided to circuit portion 782 for further processing. Circuit portion 780 also comprises a digital-to-analog (D/A) converter 750 configured to convert digital signals 706 received from circuit portion 782 into analog signals 708. Signal conditioner 722 is configured to condition the analog signals 708 for communication to the node of the first network.

Circuit portion 782 comprises a processor 726 connected to the network connector 306. Processor 726 is configured to process signals received from network connector 306 prior to being passed to D/A converter 750. Processor 726 is also configured to process digital signals 704 output from A/D converter 724, prior to being passed to the second network via network connector 308. This processing may involve signal filtering, signal encryption/decryption, and other operations to format the digital signal for communication over the second network.

The processor 726 is configured to retrieve information from and store information in memory 762. For example, processor 726 can select and retrieve one or more signal conversion algorithms 766 from memory 760. Accordingly, the memory 762 is connected to and accessible by the processor 726 through an electrical connection 764. Memory 762 may be a volatile memory and/or a non-volatile memory. For example, the memory 762 can include, but is not limited to, a random access memory (RAM), a dynamic random access memory (DRAM), a static random access memory (SRAM), a read-only memory (ROM), and/or flash memory.

One or more sets of instructions 760 are stored in memory 762. Instructions 760 can also reside, completely or at least partially, within the processor 726 during execution thereof by the signal converter 300. In this regard, memory 762 and the processor 726 can constitute machine-readable media. The term “machine-readable media”, as used here, refers to a single medium or multiple media that store the one or more sets of instructions 760. The term “machine-readable media”, as used here, also refers to any medium that is capable of storing, encoding or carrying the set of instructions 760 for execution by the signal converter 300 and that cause the signal converter 300 to perform one or more of the methodologies of the present disclosure.

It should be noted that the signal converter may include any number of first circuit portions that may be selectively connected and disconnected from the second circuit portion. For example, as shown in FIG. 7B, the signal converter comprises two first circuit portions 108₁, 108₂ and a switch 798 configured to selectively connect/disconnect the first circuit portions 108₁, 108₂ to/from the second circuit portion 782. This may be the case when, for example, the signal converter is connected to two external devices of a network. With reference to FIG. 1, signal converter 108₁ and 108_{N} are each connected to two external devices 150/122 or 152/124. The switch 132 may be the same as or similar to switch 798. Each of the first circuit portions 108₁, 108₂ can be the same as or similar to circuit portion 108 of FIG. 7A. Switch 798 may include any number of switching elements suitable for a given application.

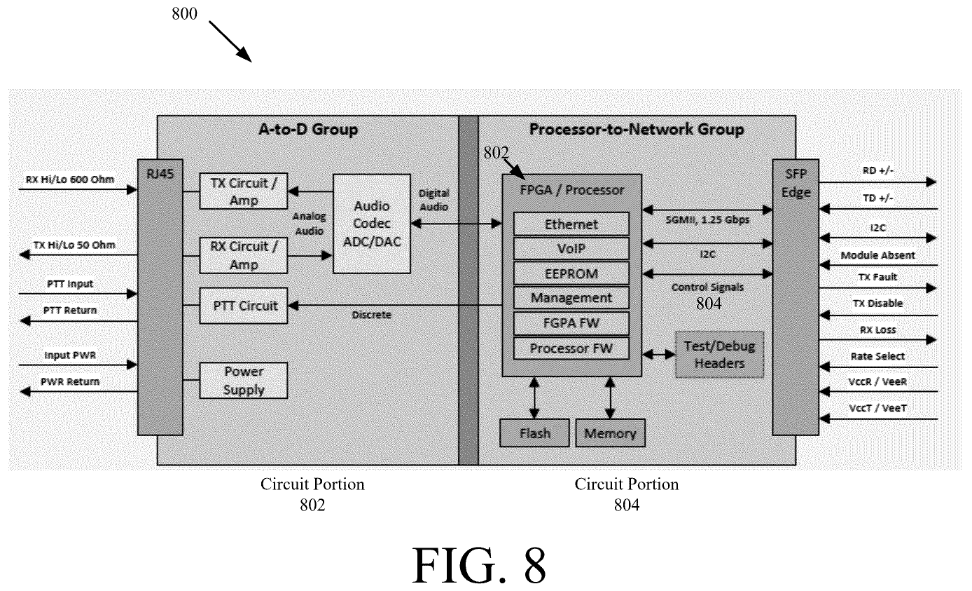

FIG. 8 provides another architecture for an internal circuit 800 of a signal converter (e.g., signal converter 108₁, 108₂, . . . , 108_{N} and/or signal converter 300 of FIG. 3). Internal circuit 800 is generally configured to facilitate communication between a radio (e.g., communication device 150 of FIG. 1) of an ad hoc communications network (e.g., network 160 of FIG. 1) (with a PTT functionality) and a telephony device (e.g., VoIP phone 116 of FIG. 1). VoIP is used to make phone calls using the Internet. The Ethernet protocol is used to facilitate a wired connection that can be used for VoIP communications. Thus, the processor of field programmable gate array (FPGA) 802 is configured to format digital information in accordance with the Ethernet protocol and VoIP. Control signals 804 can be received for enabling circuit 800, disabling circuit 800, and/or configuring operations of circuit 800.

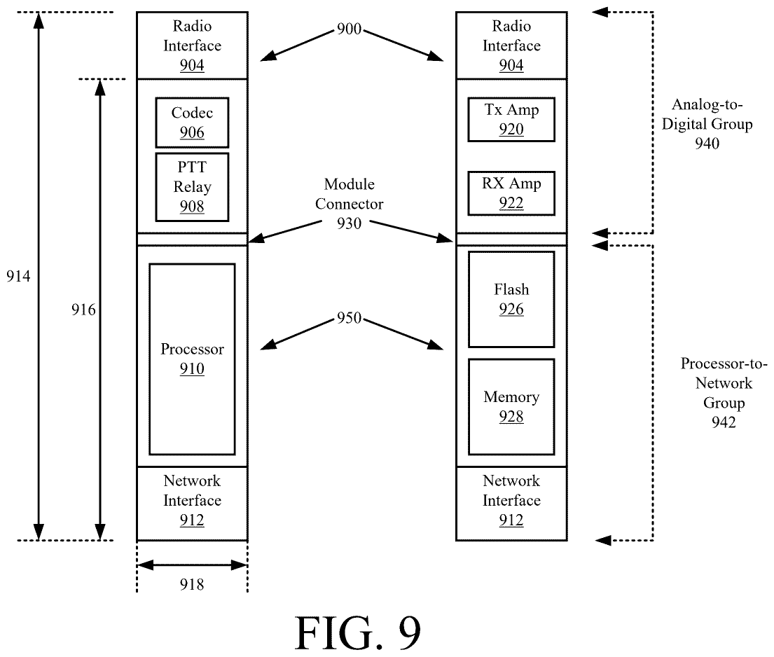

FIG. 9 provides illustrations that are useful for understanding the modularity of the present solution. As noted above, the signal converter (e.g., signal converter 108₁, 108₂, . . . , 108_{N} and/or signal converter 300 of FIG. 3) may but does not have to be configured with a back-end circuit part (e.g., part 332 of FIG. 3) to which a plurality of interchangeable front-end circuit parts (e.g., parts 338, 344 of FIG. 3) can be selectively connected. To allow for the part interchangeability, the first circuit portion is disposed on a first substrate 900 that can be selectively coupled to and decoupled from a second substrate 950 on which the second circuit portion is disposed. The substrates 900, 950 can be (de)coupled via a module connector 930. Module connector 930 is configured to establish an electrical connection between the circuit of a given front-end part and the circuit of the back-end part, when the given front-end part is coupled to the back-end part.

In the scenario of FIG. 9, each front-end part comprises an analog-to-digital group 940 of circuit components. These circuit components include a radio interface 904, a codec 906, a PTT relay 908, a transmit (Tx) amplifier 920 and a receive (Rx) amplifier 922. The radio interface 904 and codec 906 are disposed on a first side of substrate 900. The Tx amplifier 920 and Rx amplifier 922 are disposed on an opposing second side of substrate 900.

The back-end part comprises a processor-to-network group 942 of circuit components. These circuit components include a processor 910 and datastores 926, 928. Processor 910 is disposed in a first side of substrate 950. Datastores 926, 928 are disposed on an opposing second side of substrate 950.

Substrates 900, 950 may be designed to provide dimensions 914, 916 and 918. For example, dimension 914 can be 2.2 inches. Dimension 916 can be 1.77 inches, and dimension 918 can be 0.47 inches. The present solution is not limited to these particular dimensions. Dimensions 914, 916 and 918 can have any values selected in accordance with a given application.

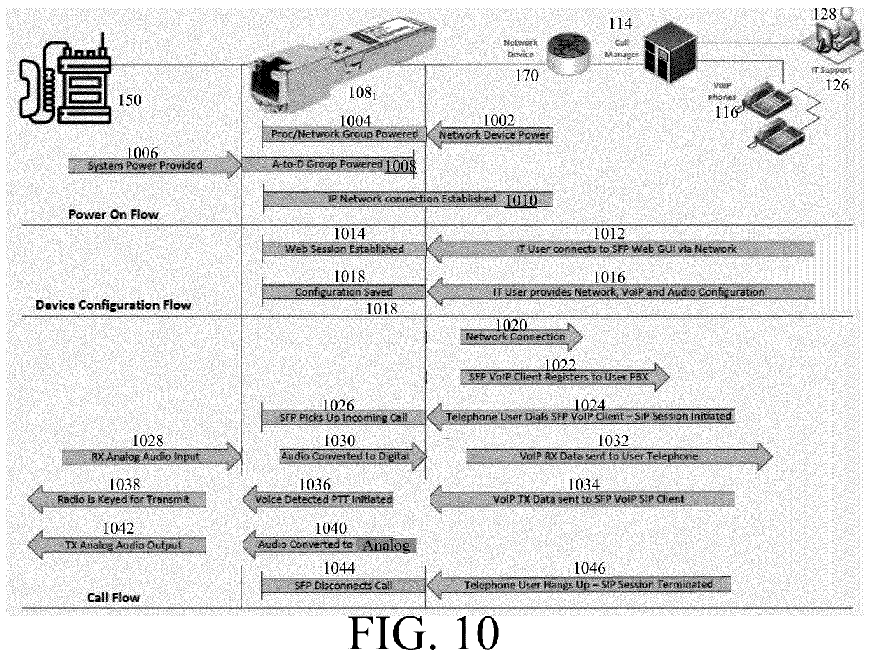

FIG. 10 provides an illustration that is useful for understanding operations of signal converter 108₁. Signal converter 108_{N} of FIG. 1 and/or signal converter 300 of FIG. 3 may be the same as or similar to signal converter 108₁. Thus, the discussion of signal converter 108₁ is sufficient for understanding operations of signal 108_{N} of FIG. 1 and/or signal converter 300 of FIG. 3.

During operations, a network device 170 provides network device power to signal converter 108₁ as shown by arrow 1002. The network device power is used in block 1004 to power the components of the processor-to-network group (e.g., processor-to-network group 942 of FIG. 9). As shown by arrow 1006, communication device 150 supplies system power to signal converter 108₁. The signal power is used in block 1008 to power the components of the analog-to-digital group (e.g., analog-to-digital group 940 of FIG. 9). In block 1010, an IP network connection is established between signal converter 108₁ and the network device 170.

Next device configuration operations are performed. In this regard, operator 128 performs user-software interactions with computing device 126 to connect to the signal converter 108₁ via the network 104, as shown by arrow 1012. The user-software interactions may be facilitated by a web-based graphical user interface (GUI). A web session is established in block 1014. Operator 128 also performs user-software interactions with computing device 126 to provide network, VoIP and audio configurations to the signal converter 108₁ via the network 104, as shown by arrow 1016. The configuration information is stored in a local memory of the signal converter 108₁ in block 1018.

Next call operations are performed. The call operations involve: establishing a network connection as shown by arrow 1020; registering the signal converter 108₁ to a private branch exchange (PBX) system as shown by arrow 1022; establishing an SIP session as shown by arrow 1024; picking up an incoming call in block 1026; receiving, by signal converter 108₁, an analog audio input from communication device 150 as shown by arrow 1028; converting, by signal converter 108₁, the analog audio input and communicate the same to the VoIP phone 116 as show by arrows 1030, 1032; receiving, by the signal converter 108₁, VoIP transmit data sent from the VoIP phone 116 over the network as shown by arrow 1034; analyzing, by the signal converter 108₁, the VoIP transmit data to detect voice data therein; initiate, by the signal converter 108₁, PTT operations as shown by arrow 1036; causing, by the signal converter 108₁, the communication device 150 to be keyed for transmit as shown by arrow 1038; performing operations by signal converter 108₁ to convert the voice data to analog audio as shown by arrow 1040; transmit the analog audio from the signal converter 108₁ to the communication device 150 as shown by arrow 1042; and performing operations by the signal converter 108₁ in block 1044 to disconnect the call in response to the SIP session being terminated (as shown by arrow 1046).

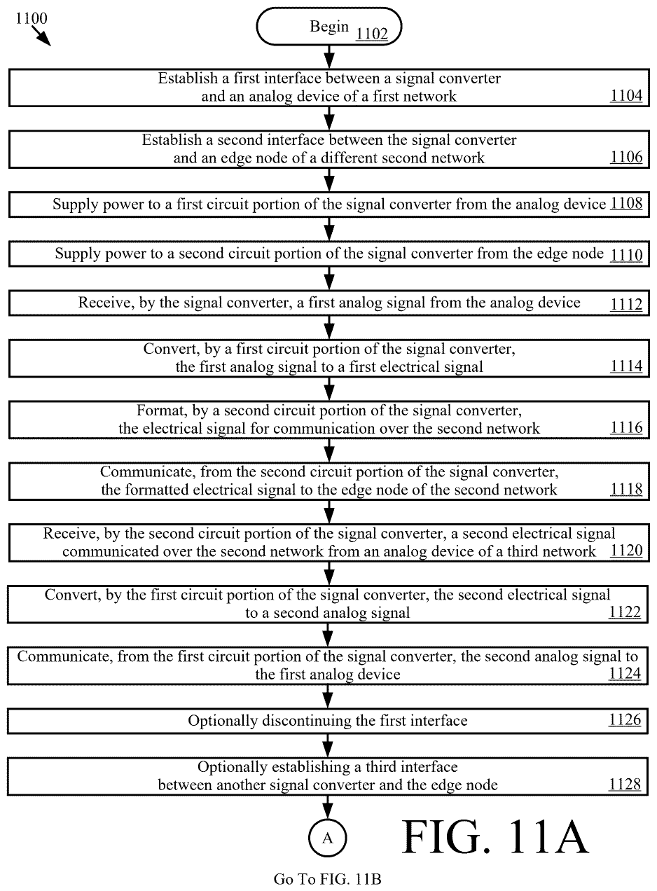

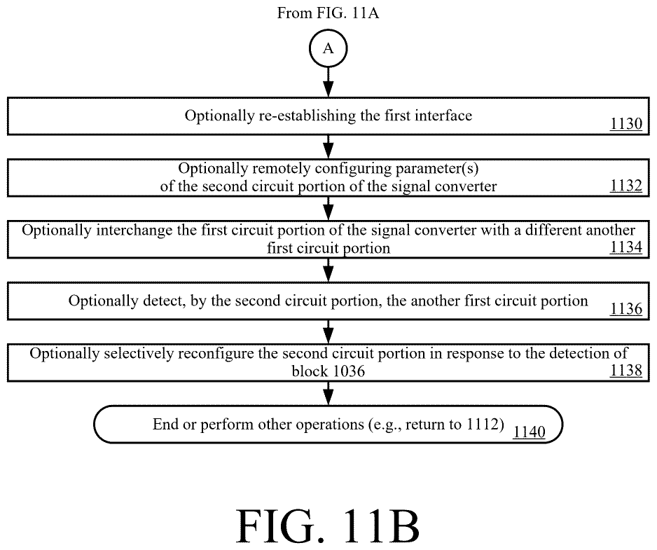

FIG. 11 provides a flow diagram of an illustrative method 1100 for operating a signal converter (e.g., signal converter 108₁, . . . , 108_{N} of FIG. 1 and/or signal converter 300 of FIG. 3). The signal converter may comprise a small form factor pluggable device configured to be plugged into an edge node and provide a communications bridge between a first network (e.g., network 160 or 162 of FIG. 1) and a second network (e.g., network 104 of FIG. 1).

Method 1100 begins with block 1102 and continues to block 1104 where a first interface is established between the signal converter and an analog device (e.g., communication device 150 of FIG. 1, sensor(s) 122 of FIG. 1, sensor(s) 130 of FIG. 1, legacy device(s) 124 of FIG. 1, or communication device 152 of FIG. 1) of the first network (e.g., network 160 or 162 of FIG. 1). A second interface is also established in block 1106 between the signal converter and an edge node (e.g., edge device 106₁ or 106₂ of FIG. 1) of the second network (e.g., network 104 of FIG. 1).

Next in block 1108, power is supplied to a first circuit portion (e.g., circuit portion 780 of FIG. 7A, and/or 802 of FIG. 8) of the signal converter from the analog device. Power is supplied in block 1110 to a second circuit portion (e.g., circuit portion 782 of FIG. 7A, and/or 804 of FIG. 8) of the signal converter from the edge node.

In block 1112, the signal converter receives a first analog signal from the analog device. The first analog signal can include, but is not limited to, a radio analog audio signal, an ear and mouth audio signal, a discrete input and output signal, a discrete relay signal, a serial data bus signal, a two-wire data bus signal, a wideband ciphertext signal, a public switched telephone network signal, and a push-to-talk signal. The first circuit portion of the signal converter converts the first analog signal (e.g., signal 702 of FIG. 7A) to a first electrical signal (e.g., signal 704 of FIG. 7A) in block 1114. The first electrical signal can include, but is not limited to, a digital signal. Any known or to be known technique for converting an analog signal to an electrical signal can be used here.

In block 1116, the second circuit portion of the signal converter formats the first electrical signal for communication over the second network. Any known or to be known technique for formatting electrical signals and/or digital data for communication over a network can be used here. For example, the digital signal is formatted to form an internet protocol signal (e.g., signal 790 of FIG. 7A). The second circuit portion of the signal converter then communicates the formatted electrical signal to the edge node of the second network, as shown by block 1118.

Subsequently, the second circuit portion of the signal converter receives a second electrical signal in block 1120. The second electrical signal (e.g., signal 792 of FIG. 7A) was communicated over the second network from an analog device (e.g., communication device 150 of FIG. 1, sensor(s) 122 of FIG. 1, sensor(s) 130 of FIG. 1, legacy device(s) 124 of FIG. 1, or communication device 152 of FIG. 1) of a third network (e.g., network 160 or 162 of FIG. 1). It should be noted that the second circuit portion may process the second electrical signal prior to passing it to the first circuit portion to (i) remove header and trailers therefrom and (ii) place it in a format suitable for communication over the first network. Techniques for performing operations (i) and/or (ii) are known. The first circuit portion of the signal converter converts the second electrical signal (e.g., signal 706 of FIG. 7A) to a second analog signal (e.g., signal 708 of FIG. 7A), as shown by block 1122. The first circuit portion of the signal converter communicates the second analog signal to the first analog device in block 1124.

Method 1100 may then continue with optional operations of blocks 1126, 1128 of FIG. 11A and 1130-1138 of FIG. 11B. The optional operations involve: (1126) discontinuing the first interface between the signal converter and an analog device of a first network; (1128) establishing a third interface between the signal converter and another analog device of the first network, while maintaining the second interface between the signal converter and the edge node of the second network; (1130) re-establishing the first interface; and/or (1132) remotely configuring parameters of the second circuit portion of the signal converter (e.g., communication or management parameters such as modulation type, gain settings, IP address, firmware, etc.). The operations of block 1126 and 1128 may be achieved by actuating a switch (e.g., switch 132 of FIG. 1).

The optional operations may additionally or alternatively involve (1134) interchanging the first circuit portion with a different another first circuit portion. The first circuit portion interchange may be achieved by: removing the first circuit portion circuit from the signal converter; and coupling the different another first circuit portion to the second circuit portion. The another first circuit portion may be configured to convert second analog signals to electrical signals. The second analog signals may have a second analog signal format different from a first analog signal format of the first analog signals.

The optional operations may additionally or alternatively involve: (1136) detecting, by the second circuit portion of the signal converter, when the first circuit portion has been replaced with the different another first circuit portion; and (1138) selectively reconfiguring the second circuit portion responsive to the detecting. The second circuit portion may be reconfigured by, for example, setting a parameter value for processing another type of signals (e.g., discrete I/O signals instead of audio signals), changing gain settings, changing discrete on/off control, and/or changing a host management interface to be used for remote control.

Subsequently, method 1100 continues to block 1140 where it ends or other operations are performed. The other operations can include, but are not limited to, returning to block 1102, returning to block 1112, and/or receiving, by the signal controller, a control signal from a remote device (e.g., computing device 126 of FIG. 1) to disable operations of the first circuit portion and/or the second circuit portion, while another signal converter connected to the edge device is enabled.

In view of the forgoing discussion, the present solution concerns implementing systems and methods for operating a signal converter. The methods comprise: establishing a first interface between the signal converter and an analog device of a first network, and a second interface between the signal converter and an edge node of a different second network; supplying power to a first circuit portion of the signal converter from the analog device, and power to a second circuit portion of the signal converter from the edge node; receiving, by the first circuit portion, a first analog signal from the analog device; converting, by the first circuit portion, the first analog signal to a first electrical signal; formatting, by the second circuit portion, the first electrical signal for communication over the second network; and communicating, from the second circuit portion, the formatted first electrical signal to the edge node.

The first analog signal may include, but is not limited to, a radio analog audio signal, an ear and mouth audio signal, a discrete input and output signal, a discrete relay signal, a serial data bus signal, a two-wire data bus signal, a wideband ciphertext signal, a public switched telephone network signal, and a push-to-talk signal. The first electrical signal may include, but is not limited to, a digital signal and/or an internet protocol signal. The signal converter can include, but is not limited to, a small form factor pluggable device configured to be plugged into the edge node and provide a communications bridge between the first network and the second network.

The methods may also involve: receiving, by the second circuit portion of the signal converter, a second electrical signal communicated over the second network from an analog device of a third network; converting, by the signal converter, the second electrical signal into a second analog signal; and providing the second analog signal from the signal converter to the analog device.

Additionally or alternatively, the methods may comprise: discontinuing said first interface between the signal converter and an analog device of a first network; and establishing a third interface between the signal converter and another analog device of the first network, while maintaining the second interface between the signal converter and the edge node of the second network.

Additionally or alternatively, the methods may comprise: receiving a control signal from a remote device to disable operations of the first circuit portion and or the second circuit portion, while another signal converter connected to the edge device is enabled; remotely configuring one or more communication or management parameters of the second circuit portion of the signal converter; interchanging the first circuit portion with a different another first circuit portion; detecting, by the second circuit portion of the signal converter, when the first circuit portion has been replaced with the different another first circuit portion; and/or selectively reconfiguring the second circuit portion responsive to said detecting. The first circuit portion may be interchanged by: removing the first circuit portion circuit from the signal converter; and coupling the different another first circuit portion to the second circuit portion. The different another first circuit portion may be configured to convert second analog signals to electrical signals, the second analog signals having a second analog signal format different from a first analog signal format of the first analog signals.

The present solution also concerns a signal converter. The signal converter may include, but is not limited to, a small form factor pluggable device configured to be plugged into the edge node and provide a communications bridge between the first network and the second network. The signal converter comprises: a first interface (e.g., connector 308 of FIG. 3) configured to be connected between the signal converter and an analog device of a first network; a second interface (e.g., connector 306 of FIG. 3) configured to be connected between the signal converter and an edge node of a different second network; a first circuit portion (e.g., circuit portion 780 of FIG. 7A) connected between the first and second interfaces, and configured to receive power from the analog device via the first interface, receive a first analog signal from the analog device, and convert the first analog signal to a first electrical signal; and a second circuit portion (e.g., circuit portion 782 of FIG. 7A) connected between the first circuit portion and the second interface, and configured to receive power from the edge node via the second interface, format the first electrical signal for communication over the second network, and communicate the formatted first electrical signal to the edge node.

The second circuit portion may also be configured to receive a second electrical signal communicated over the second network from an analog device of a third network. The first circuit portion may also be configured to convert the second electrical signal into a second analog signal. The first interface may also be configured to communicate the second analog signal from the signal converter to the analog device.

The signal converter may also comprise a switch (e.g., switch 132 of FIGS. 1 and/or 798 of FIG. 7B) configured to selectively discontinue first interface between the signal converter and an analog device of a first network, and establish a third interface between the signal converter and another analog device of the first network (e.g., while maintaining the second interface between the signal converter and the edge node of the second network).

The second circuit portion may also be configured to: receive a control signal from a remote device to disable operations of the first circuit portion and or the second circuit portion; be remotely controlled to change one or more communication or management parameters of the second circuit portion of the signal converter; detect when the first circuit portion has been replaced with the different another first circuit portion; and/or selectively reconfigure one or more of its signal processing operations responsive to said detecting.

The first circuit portion may also be configured to be interchanged with a different another first circuit portion that is configured to convert second analog signals to electrical signals. The second analog signals may have a second analog signal format different from a first analog signal format of the first analog signals.

The described features, advantages and characteristics disclosed herein may be combined in any suitable manner. One skilled in the relevant art will recognize, in light of the description herein, that the disclosed systems and/or methods can be practiced without one or more of the specific features. In other instances, additional features and advantages may be recognized in certain scenarios that may not be present in all instances.

As used in this document, the singular form “a”, “an”, and “the” include plural references unless the context clearly dictates otherwise. Unless defined otherwise, all technical and scientific terms used herein have the same meanings as commonly understood by one of ordinary skill in the art. As used in this document, the term “comprising” means “including, but not limited to”.

Although the systems and methods have been illustrated and described with respect to one or more implementations, equivalent alterations and modifications will occur to others skilled in the art upon the reading and understanding of this specification and the annexed drawings. In addition, while a particular feature may have been disclosed with respect to only one of several implementations, such feature may be combined with one or more other features of the other implementations as may be desired and advantageous for any given or particular application. Thus, the breadth and scope of the disclosure herein should not be limited by any of the above descriptions. Rather, the scope of the invention should be defined in accordance with the following claims and their equivalents.

We claim:

1. A method for operating a signal converter, comprising:
establishing a first interface between the signal converter and an analog device of a first network, and a second interface between the signal converter and an edge node of a different second network;
supplying power to a first circuit portion of the signal converter from the analog device, and power to a second circuit portion of the signal converter from the edge node;
receiving, by the first circuit portion, a first analog signal from the analog device;
converting, by the first circuit portion, the first analog signal to a first electrical signal;
formatting, by the second circuit portion, the first electrical signal for communication over the second network; and
communicating, from the second circuit portion, the formatted first electrical signal to the edge node.

2. The method according to claim 1, wherein the first analog signal comprises a radio analog audio signal, an ear and mouth audio signal, a discrete input and output signal, a discrete relay signal, a serial data bus signal, a two-wire data bus signal, a wideband ciphertext signal, a public switched telephone network signal, and a push-to-talk signal.

3. The method according to claim 1, wherein the first electrical signal comprises an internet protocol signal.

4. The method according to claim 1, wherein the signal converter comprises a small form factor pluggable device configured to be plugged into the edge node and provide a communications bridge between the first network and the second network.

5. The method according to claim 1, further comprising:
receiving, by the second circuit portion of the signal converter, a second electrical signal communicated over the second network from an analog device of a third network;
converting, by the signal converter, the second electrical signal into a second analog signal; and
providing the second analog signal from the signal converter to the analog device.

6. The method according to claim 1, further comprising:
discontinuing said first interface between the signal converter and an analog device of a first network; and
establishing a third interface between the signal converter and another analog device of the first network, while maintaining the second interface between the signal converter and the edge node of the second network.

7. The method according to claim 1, further comprising receiving a control signal from a remote device to disable operations of the first circuit portion and or the second circuit portion, while another signal converter connected to the edge device is enabled.

8. The method according to claim 1, further comprising remotely configuring one or more communication or management parameters of the second circuit portion of the signal converter.

9. The method according to claim 1, further comprising interchanging the first circuit portion with a different another first circuit portion by:
removing the first circuit portion circuit from the signal converter; and
coupling the different another first circuit portion to the second circuit portion;
wherein the different another first circuit portion is configured to convert second analog signals to electrical signals, the second analog signals having a second analog signal format different from a first analog signal format of the first analog signals.

10. The method according to claim 9, further comprising:
detecting, by the second circuit portion of the signal converter, when the first circuit portion has been replaced with the different another first circuit portion; and
selectively reconfiguring the second circuit portion responsive to said detecting.

11. A signal converter, comprising:
a first interface configured to be connected between the signal converter and an analog device of a first network;
a second interface configured to be connected between the signal converter and an edge node of a different second network;
a first circuit portion connected between the first and second interfaces, and configured to receive power from the analog device via the first interface, receive a first analog signal from the analog device, and convert the first analog signal to a first electrical signal; and
a second circuit portion connected between the first circuit portion and the second interface, and configured to receive power from the edge node via the second interface, format the first electrical signal for communication over the second network, and communicate the formatted first electrical signal to the edge node.

12. The signal converter according to claim 11, wherein the first analog signal comprises a radio analog audio signal, an ear and mouth audio signal, a discrete input and output signal, a discrete relay signal, a serial data bus signal, a two-wire data bus signal, a wideband ciphertext signal, a public switched telephone network signal, and a push-to-talk signal.

13. The signal converter according to claim 11, wherein the first electrical signal comprises an internet protocol signal.

14. The signal converter according to claim 11, wherein the signal converter comprises a small form factor pluggable device configured to be plugged into the edge node and provide a communications bridge between the first network and the second network.

15. The signal converter according to claim 11, wherein:
the second circuit portion is further configured to receive a second electrical signal communicated over the second network from an analog device of a third network;
the first circuit portion is further configured to convert the second electrical signal into a second analog signal; and
the first interface is further configured to communicate the second analog signal from the signal converter to the analog device.

16. The signal converter according to claim 11, further comprising a switch configured to selectively
discontinue first interface between the signal converter and an analog device of a first network, and
establish a third interface between the signal converter and another analog device of the first network, while maintaining the second interface between the signal converter and the edge node of the second network.

17. The signal converter according to claim 11, wherein the second circuit portion is further configured to receive a control signal from a remote device to disable operations of the first circuit portion and or the second circuit portion.

18. The signal converter according to claim 11, wherein the second circuit portion is configured to be remotely controlled to change one or more communication or management parameters of the second circuit portion of the signal converter.

19. The signal converter according to claim 11, wherein the first circuit portion is configured to be interchanged with a different another first circuit portion that is configured to convert second analog signals to electrical signals, the second analog signals having a second analog signal format different from a first analog signal format of the first analog signals.

20. The signal converter according to claim 19, wherein the second circuit portion is further configured to:
detect when the first circuit portion has been replaced with the different another first circuit portion; and
selectively reconfigure one or more of its signal processing operations responsive to said detecting.
